(19) United States
(12) Patent Application Publication
(10) Pub. No.: US 2011/0259404 A1
(43) Pub. Date: Oct. 27, 2011

(54) PHOTOVOLTAIC MODULE FRAME

(76) Inventor: Byung-Rak JANG, Gwangju-si (KR)

(21) Appl. No.: 12/940,190

(22) Filed: Nov. 5, 2010

(30) Foreign Application Priority Data
Apr. 23, 2010 (KR) 10-2010-0038187

(51) Int. Cl. H01L 31/048

(52) U.S. Cl. 136/251

(57) ABSTRACT

An apparatus for a photovoltaic module frame assembly comprising a frame member including a vertical member and horizontal member that cover the outer circumference the photovoltaic module, which transforms solar energy into electric energy, and corner member that performs connections and fixation between the horizontal member and vertical member, which provides a solution to alleviate traditional frame structure issues that relate to the sharpness of the corner so that any accidents that may be caused by the corner can be prevented and enhance safety. Also a groove is included to fix the frame onto the corner member that, which covers the photovoltaic module and does not have any sides, and allows accurate coupling by fitting into the frame member so that various designs and formations can be provided.

### CROSS REFERENCE

This application claims foreign priority under Paris Convention and 35 U.S.C. §119 to Korean Patent Application No. 10-2010-0038187, filed Apr. 23,2010 with the Korean Intellectual Property Office.

### BACKGROUND OF THE INVENTION

1. Technical Field

The present invention relates to an apparatus for a photovoltaic module frame assembly comprising a frame member including a vertical member and horizontal member that cover the outer circumference the photovoltaic module, which transforms solar energy into electric energy, and corner member that performs connections and fixation between the horizontal member and vertical member, which provides a solution to alleviate traditional frame structure issues that relate to the sharpness of the corner so that any accidents that may be caused by the corner can be prevented and enhance safety. Also a groove is included to fix the frame onto the corner member that, which covers the photovoltaic module and does not have any sides, and allows accurate coupling by fitting into the frame member so that various designs and formations can be provided.

2. Description of the Related Art

The present invention relates to a photovoltaic module frame for transforming solar energy into electric energy having greater solidity and accurate fixation in terms of holding lock.

In general, photovoltaic modules stand for devices that transform solar energy into electric energy and are installed in locations where the frame covers the border.

FIG. 1 illustrates the perspective view of a traditional photovoltaic module frame. According to the illustration in FIG. 1, traditional frames allows the corner key to be inserted inside by cutting the horizontal member (1) and vertical member (2) by 45° so that mutual coupling can happen. By simply inserting into the corner key, this method causes safety issues due to the sharpness of the module cornering, which needs further actions operated by the installer. Also, the actions operated to solve the sharpness issue may cause damage onto the frame and lower productivity, efficiency and stability.

Furthermore, traditional photovoltaic module frames have the horizontal member and vertical member to couple directly, which may lower solidity and accuracy in coupling so that the exterior is faulty, and the frame can be twisted from strong wind and other disturbance, which may cause damage to the photovoltaic module that, is inserted into the frame.

### SUMMARY OF THE INVENTION

Therefore, the present invention was proposed to solve the general issues of traditional devices.

The purpose of the present invention is to prevent any damage of the photovoltaic module by allowing the frame member to accurately and solidly connect to prevent any twisting of the frame member.

Another purpose of the present invention is to provide safety to the installer by rounding the corner of the frame member and corner member, which causes the corner member to have various forms and can mass produce photovoltaic module frames with beautiful exterior and various designs and install in various locations.

The purpose of the present invention is to provide a stable and solid photovoltaic module frame by preventing the corner member to break away from the frame member by having a wedge shaped protrusion on the corner member lock onto the protrusion of the frame member.

In addition, the purpose of the present invention is to reduce the operation time and fault rate of the photovoltaic module frames by providing an injection type coupling between the frame member and corner member so that no additional equipment is needed and no further support is necessary within the frame that forms a rectangle or polygon shape in solid coupling of the frame.

The purpose of the present invention is to provide quality assurance by standardizing the photovoltaic module frame by promoting an accurate coupling between the frame member and other frame members from the mentioned corner member and furthermore, resolve the cracking issue in between the connected frame members.

For the purpose of solving issues the present invention has been composed to improve traditional photovoltaic module frames.

According to the preferred embodiment, the present invention comprises of a frame member including a vertical member and horizontal member that cover the outer circumference the photovoltaic module, which transforms solar energy into electric energy, and corner member that performs connections and fixation between the horizontal member and vertical member. However, the frame member that is exposed to the exterior or the corner member that is molded to have a rounded shape by operating cutting work to blunt the sharp corner of the corner member and provide an enhanced quality and stable product.

According to the preferred embodiment, the present invention comprises of a frame member including a vertical member and horizontal member that is mutually coupled forming a rectangular structure to cover the photovoltaic module frame.

Also, the horizontal member and vertical member includes a guide groove formed to interpolate the corner member by guiding and positioned at the lower portion of the photovoltaic module frame locking groove that is formed to interpolate and operate holding of a certain portion of photovoltaic module frame.

According to the preferred embodiment of the present invention, the lower portion of the horizontal member and vertical member is formed to have the photovoltaic module fix onto certain structures and is internally extended to form a flange.

According to the preferred embodiment of the present invention, the inside of the guide groove includes an additional loosening prevention protrusion so that the corner member can lock onto the loosening prevention protrusion and prevent detachment from strong wind or other disturbances and pressures when the frame member and corner member are coupled together.

According to the preferred embodiment of the present invention, the corner member is exposed to exterior and includes a body unit that forms part of the horizontal member and vertical member and an externally extended protrusion on both sides of the body unit.

According to the preferred embodiment of the present invention, the body unit cross-section forms a triangle, rectangle or a polygon.

According to the preferred embodiment of the present invention, the protrusion is formed on both sides of the body unit so that the horizontal member and vertical member can connect and includes a lock on one side.

According to the preferred embodiment of the present invention, the lock unit allows the loosening prevention protrusion formed within the guide groove to lock onto the lock unit when the guide groove of the frame member is inserted into the protrusion so that it prevents the corner member being detached from the frame member.

According to the preferred embodiment of the present invention, the lock unit is a wedge shape or a hook shape pattern that is formed with repetition.

The present invention holds the following effects from the composition and coupling relationship.

The present invention, photovoltaic module frame, is formed to have the corner of the corner member or frame member that is exposed to the exterior to be round so that the installers can be provided safety and quality improvement. Furthermore, the corner member can be in various forms so that the product can be mass produced in various designs and can be installed in many places. At the same time, prevent the frame member from twisting and damaging the photovoltaic module by accurate and solid connection with the frame member from the body unit that forms part of the horizontal member and vertical member.

The present invention, photovoltaic module frame, forms a wedge shaped protrusion on the corner member so that the protrusion can lock onto the loosening prevention protrusion of the frame member to prevent any detachment and better fix the photovoltaic module.

The present invention, photovoltaic module frame, allows simple injection methods for coupling of the frame member and the corner member without any additional equipment. The frame coupled to reduce operation time and reduce fault rate without any additional support onto the interior of the frame forming a rectangular or polygonal shape.

The present invention, photovoltaic module frame, has the corner member that includes the body unit, which forms part of the horizontal member and vertical member, to provide quality assurance by standardizing the photovoltaic module frame by promoting an accurate coupling between the frame member and other frame members from the mentioned corner member and furthermore, resolve the cracking issue in between the connected frame members.

### BRIEF DESCRIPTION OF THE DRAWINGS

FIG. 1 illustrates the perspective view of the traditional photovoltaic module frame.

FIG. 2 illustrates the perspective view of the photovoltaic module frame for preferred embodiment.

FIG. 3 illustrates the top view of the photovoltaic module frame for preferred embodiment.

FIG. 4a and FIG. 4b illustrate the cross-sectional view of the frame member of the photovoltaic module frame for preferred embodiment.

FIG. 5 illustrates the perspective view of the corner member of the photovoltaic module frame for preferred embodiment.

FIG. 6 illustrates the top view of the corner member of the photovoltaic module frame for preferred embodiment.

FIG. 7a and FIG. 7b illustrates the cross-sectional view of the corner member of the photovoltaic module frame for preferred embodiment.

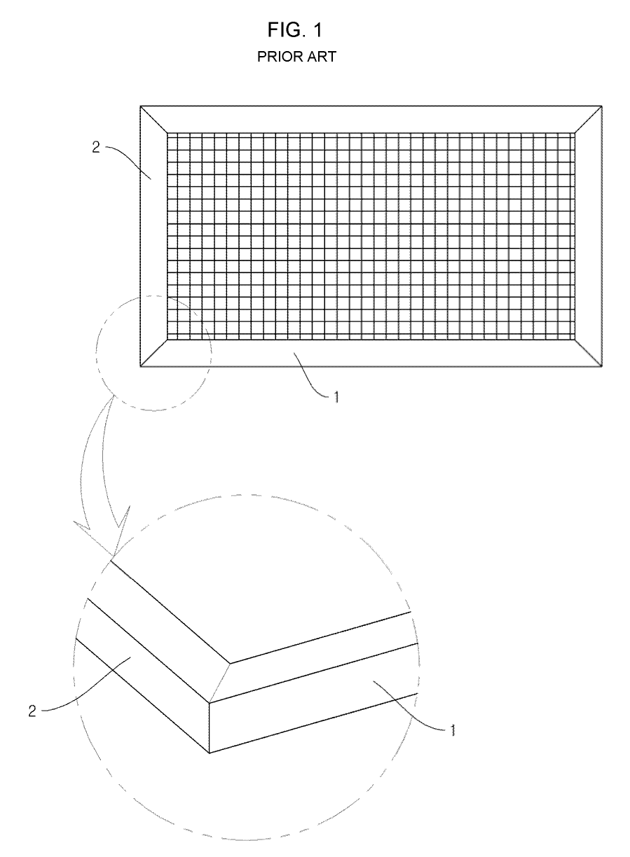

<Significant Terms for Figures>

| 10: | frame | 11: | horizontal |
|---|---|---|---|
| | member | | member |
| 12: | vertical | 20: | corner |
| | member | | member |
| 21: | body unit | 22: | protrusion |
| 111, 121, 211: | photovoltaic module locking groove | | |
| 113, 123: | guide groove | 115, 125: | flange |
| 221: | lock | 1131, 1231: | loosening |
| | | | prevention |
| | | | protrusion |

### DESCRIPTION OF SPECIFIC EMBODIMENTS

The present invention relates to an apparatus for a photovoltaic module frame assembly comprising a frame member including a vertical member and horizontal member that cover the outer circumference the photovoltaic module, which transforms solar energy into electric energy, and corner member that performs connections and fixation between the horizontal member and vertical member, which provides a solution to alleviate traditional frame structure issues that relate to the sharpness of the corner so that any accidents that may be caused by the corner can be prevented and enhance safety. Also a groove is included to fix the frame onto the corner member that, which covers the photovoltaic module and does not have any sides, and allows accurate coupling by fitting into the frame member so that various designs and formations can be provided.

The figures attached illustrate the preferred embodiment of the present invention. All terms that are not defined in particular are to follow the general terms that abides by the terms in the field this present invention relates and when a term defined conflicts with any other term meaning it follows the definition stated in this document. Especially, the composition and methods of the preferred embodiment is for the better explanation and not to limit the scope of the invention.

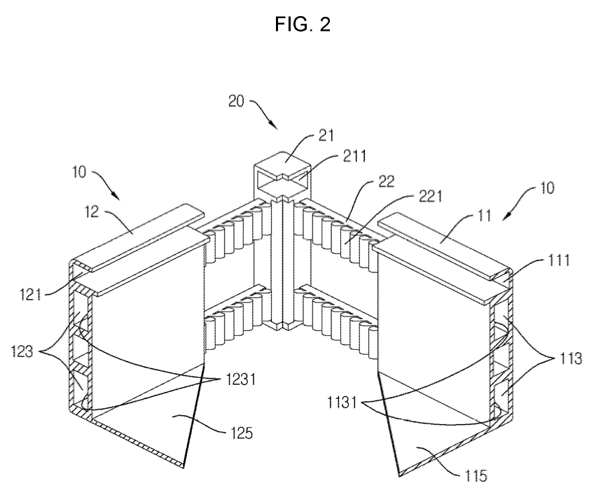

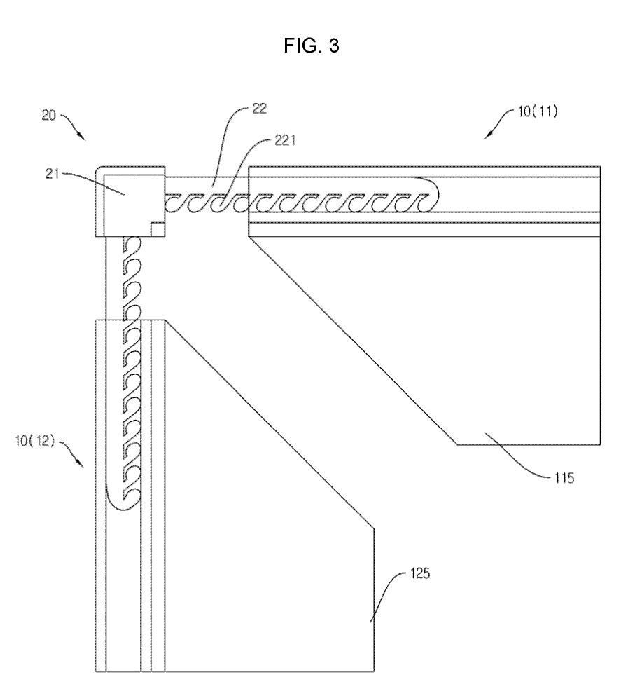

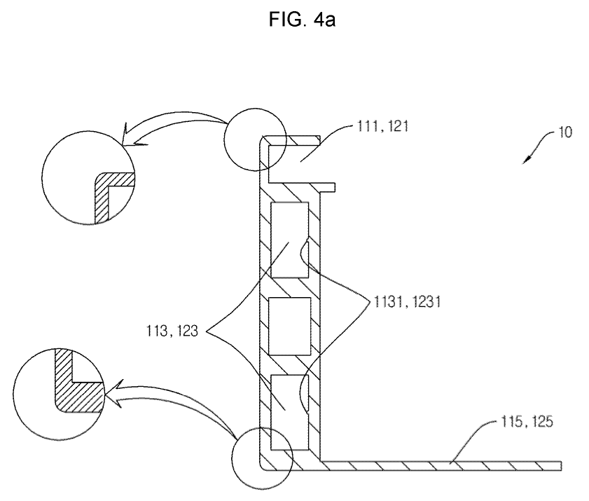

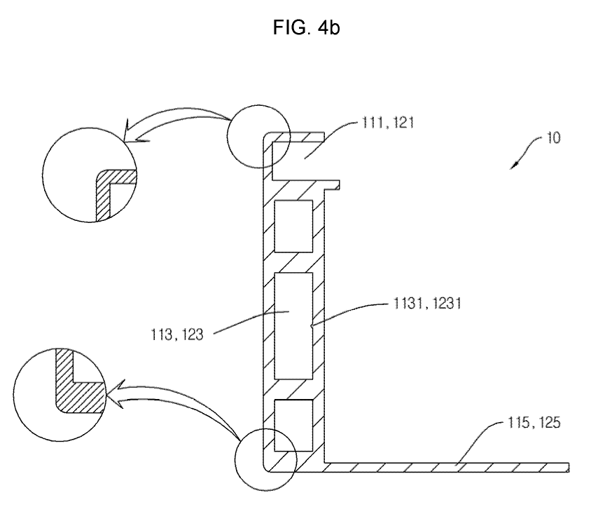

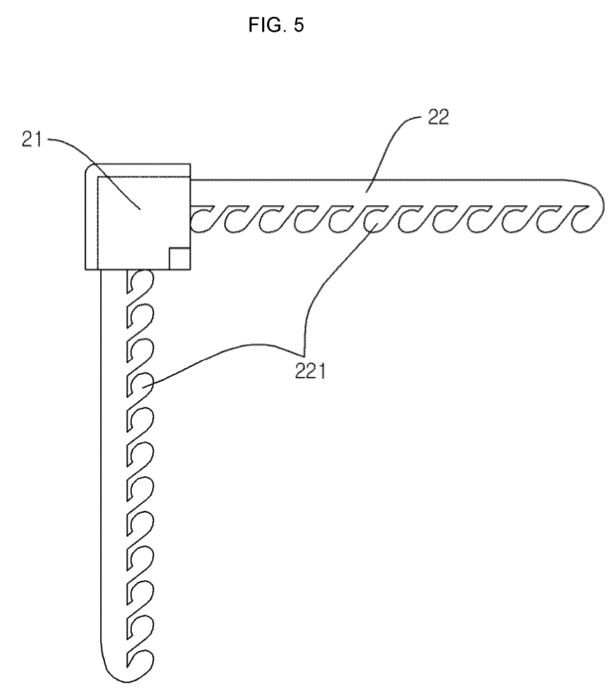

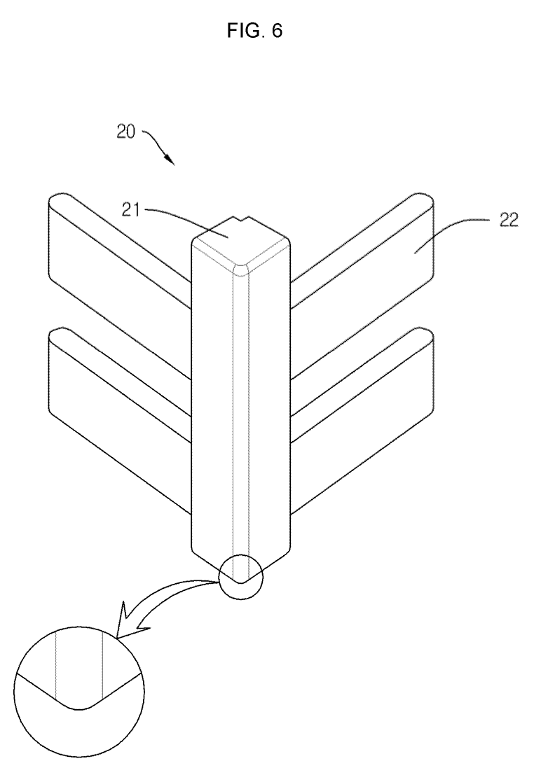

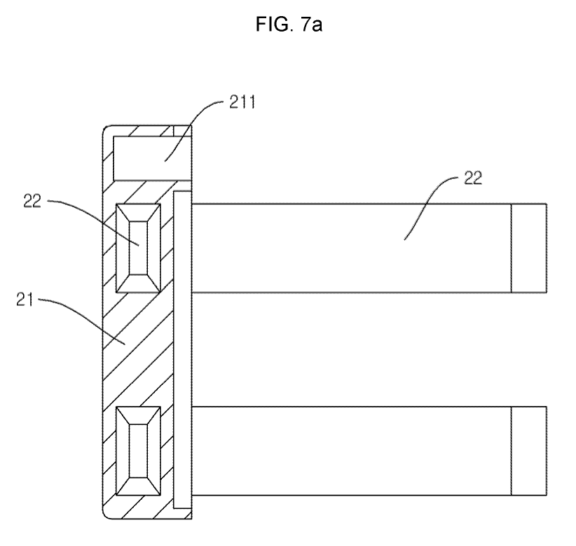

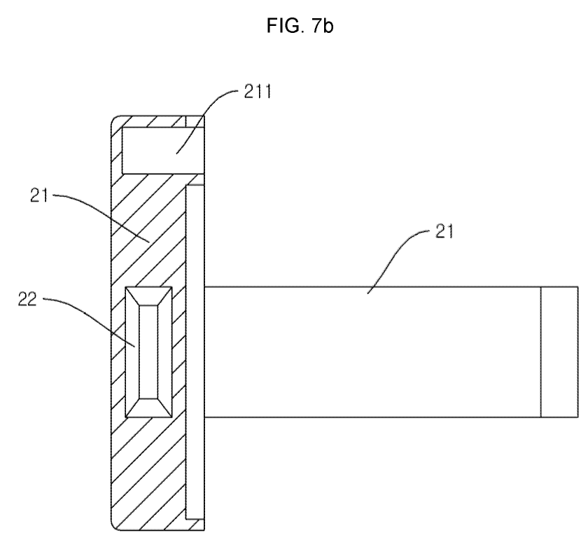

FIG. 2 illustrates the perspective view of the photovoltaic module frame for preferred embodiment. FIG. 3 illustrates the top view of the photovoltaic module frame for preferred embodiment. FIG. 4a or FIG. 4b illustrates the cross-sectional view of the frame member of the photovoltaic module frame for preferred embodiment. FIG. 5 illustrates the perspective view of the corner member of the photovoltaic module frame for preferred embodiment. FIG. 6 illustrates the top view of the corner member of the photovoltaic module frame for preferred embodiment. FIG. 7a or FIG. 7b illustrates the cross-sectional view of the corner member of the photovoltaic module frame for preferred embodiment.

As illustrated in FIG. 2 and FIG. 3, the present invention comprises of a frame member (10) including a horizontal member (11) and vertical member (12) that cover the outer circumference the photovoltaic module, which transforms solar energy into electric energy, and corner member (20) that performs connections and fixation between the horizontal member (11) and vertical member (12). However, the frame member (10) that is exposed to the exterior or the corner member (20) that is molded to have a rounded shape by operating cutting work to blunt the sharp corner of the corner member (20) and provide an enhanced quality and stable product.

The frame member (10) including a horizontal member (11) and vertical member (12) that is mutually coupled forming a rectangular structure to cover the photovoltaic module frame.

The horizontal member (11) and vertical member (12) includes a guide groove (113, 123) formed to interpolate the corner member by guiding and positioned at the lower portion of the photovoltaic module frame locking groove (111, 121) that is formed to interpolate and operate holding of a certain portion of photovoltaic module frame. Also, the lower portion of the horizontal member (11) and vertical member (12) is formed to have the photovoltaic module fix onto certain structures and is internally extended to form a flange (115, 125).

The photovoltaic module guide groove (113, 123) is formed on the upper portion of the horizontal member (11) and vertical member (12) includes and should be able to partially insert into the outer circumference of the photovoltaic module to fix without any additional methods. Therefore, the photovoltaic module frame locking groove (111, 121) depth and width should be sufficient to prevent detachment of the photovoltaic module.

The guide groove (113, 123) is formed on the lower portion of the photovoltaic module frame locking groove (111, 121) and is included according to the following protrusion number of the corner member (20) as shown in FIG. 4a or FIG. 4b and includes more than one guide groove (113, 123).

Also, an additional loosening prevention protrusion (1131, 1231) is included within the guide groove (113, 123) so that the protrusion following the corner member (20) can lock on to an additional loosening prevention protrusion (1131, 1231) and prevent detachment from strong wind or other disturbances and pressures when the frame member (10) and corner member (20) are coupled together.

The flange (115, 125) is formed on the lower portion of the horizontal member (11) and vertical member (12) and provides certain area so that the photovoltaic module frame can fix onto a structure or support.

On the other hand, the flange (115, 125) can have locking holes on one side to use bolts as a matter of connection and fixation.

Furthermore, as illustrated in FIG. 4a and FIG. 4b, the frame member (10) forms the corner exposed to exterior to be round and operates cutting process to have a round and smooth image so that the installers can be provided safety and enhance the domestic and international quality standards.

When the corner member (20) is exposed to exterior and is comprised by a body unit (21) that forms a portion of the horizontal member (11) and vertical member (12) and protrusion (22) that is externally extended on both sides of the body unit (21).

The body unit (21) forms the actual exterior of the corner member (20) that locates in between the horizontal member (11) and vertical member (12) and helps form various shapes such as having triangular, rectangular or polygonal cross-sections. As illustrated in FIG. 6, the corner of the body unit (21), which is shown in shades in FIG. 6, has a round shape or operates chamfering to resolve the sharpness issues of the corner. This prevents any damage on the skin or tripping of the installers and solves known safety issues.

Thus, the unit body (21) that is the actual exterior of the corner member, which is sensitive to conditions where accidents occur frequently and need to meet a certain level of quality in international standards, the corner portion must be shaped round before the horizontal member and vertical member couples to provide a non sharp corner where the sides meet and provide a smooth image of the exterior so that installers can be safe from accidents and the product can meet the expectations of domestic and international quality standards.

Also, on the upper part of the body unit (21) it includes a photovoltaic module locking groove (211) that fits in the corner of the photovoltaic module.

The photovoltaic module locking groove (211) is provided to allow the corner of the photovoltaic module, like the photovoltaic module locking groove (121) included on the frame member (10), to fit a portion and fix the photovoltaic module. At this time, the photovoltaic module locking groove (211) of the body unit (21) should have the similar width and height compared to the photovoltaic module locking groove (111, 121) of the frame member (10).

The protrusion (22) is formed on both sides of the body unit (21) so that the horizontal member (11) and vertical member (12) can connect and also includes a lock (221) on one side.

The lock (221) is a wedge shape or a hook shape pattern that is formed with repetition and when the protrusion (22) is inserted into the guide groove (113, 123) the lock (221) is locked onto the loosening prevention protrusion (1131, 1231) formed within the guide groove (113, 123) so that the corner member (20) does not detach from the frame member (10).

On the other hand, the end of the protrusion (22) should be formed in a round shape so that the protrusion (22) can insert smoothly into the guide groove (113, 123).

The present invention has the characteristics of having a photovoltaic module frame that is covered in a rectangular shape with corner members that have protrusions, which respond to the molding sides of the horizontal frame and vertical frame that are formed by extrusion molding of photovoltaic module frames to convert solar energy into electric energy.

Furthermore, the present invention allows solid and accurate connection of the frame member from the corner member to prevent any twisting of the frame member that damage the photovoltaic module, and also make the frame member and corner member round by operating cutting work to blunt the sharp corner of that may cause any damage on the skin or tripping of the installers and any other safety issues, furthermore, this will improve the quality. The body unit of the corner member can form various shapes from triangular, rectangular and polygonal and operate mass production to install in various locations.

Also, the frame member and corner member can be coupled with simple injection methods without any additional equipment, and no further support is necessary within the frame that forms a rectangle or polygon shape in solid coupling of the frame. Furthermore, reduces operation time and reduce fault rate.

Also, quality assurance can be assured by standardizing the photovoltaic module frame by promoting an accurate coupling between the frame member and other frame members from the mentioned corner member and furthermore, resolve the cracking issue in between the connected frame members.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. The photovoltaic module frame comprising a frame member including a vertical member and horizontal member that cover the outer circumference the photovoltaic module, which transforms solar energy into electric energy, and corner member that performs connections and fixation between the horizontal member and vertical member, which provides a solution to alleviate traditional frame structure issues that relate to the sharpness of the corner so that any accidents that may be caused by the corner can be prevented and enhance safety. Also a groove is included to fix the frame onto the corner member that, which covers the photovoltaic module and does not have any sides, and allows accurate coupling by fitting into the frame member so that various designs and formations can be provided. Furthermore, the horizontal member and vertical member includes a guide groove formed to interpolate the corner member by guiding and positioned at the lower portion of the photovoltaic module frame locking groove that is formed to interpolate and operate holding of a certain portion of photovoltaic module frame.

2. The apparatus of claim 1, wherein the lower portion of the horizontal member and vertical member is formed to have the photovoltaic module fix onto certain structures and is internally extended to form a flange.

3. The apparatus of claim 1, wherein an additional loosening prevention protrusion is included within the guide groove so that the protrusion following the corner member can lock on to an additional loosening prevention protrusion and prevent detachment from strong wind or other disturbances and pressures when the frame member and corner member are coupled together.

4. The apparatus of claim 1, wherein the corner member is exposed to exterior and is comprised by a body unit that forms a portion of the horizontal member and vertical member and protrusion that is externally extended on both sides of the body unit.

5. The apparatus of claim 4, wherein the body unit forms in various shapes such as having triangular, rectangular or polygonal cross-sections.

6. The apparatus of claim 4, wherein the protrusion is formed on both sides of the body unit so that the horizontal member and vertical member can connect and includes a lock on one side.

7. The apparatus of claim 6, wherein the lock unit allows the loosening prevention protrusion formed within the guide groove to lock onto the lock unit when the guide groove of the frame member is inserted into the protrusion so that it prevents the corner member being detached from the frame member.

8. The apparatus of claim 6, wherein the lock unit is a wedge shape or a hook shape pattern that is formed with repetition.
